(19) United States
(12) Patent Application Publication
(10) Pub. No.: US 2020/0176235 A1
(43) Pub. Date: Jun. 4, 2020

(54) PHYSICAL VAPOR DEPOSITION WITH A DUAL-SHUTTER

(71) Applicant: International Business Machines Corporation, Armonk, NY (US)

(72) Inventors: Hsueh-Chung Chen, Cohoes, NY (US); Wei Wang, Yorktown Heights, NY (US)

(21) Appl. No.: 16/204,168

(22) Filed: Nov. 29, 2018

(51) Int. Cl. H01J 37/34; C23C 14/54; C23C 14/34

(52) U.S. Cl. CPC H01J 37/3447; C23C 14/3407; H01J 37/3435; C23C 14/54

(57) ABSTRACT

Techniques that facilitate physical vapor deposition with a dual-shutter are provided. In one example, a system includes a target plate, a first shutter plate and a second shutter plate. The target plate is associated with a voltage for physical vapor deposition. The first shutter plate comprises a first set of openings. The second shutter plate comprises a second set of openings. The first shutter plate and the second shutter plate are located between the target plate and a substrate. Furthermore, the first shutter and the second shutter rotate.

### BACKGROUND

The subject disclosure relates to film deposition, and more specifically, to physical vapor deposition.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, systems, devices, computer-implemented methods, apparatus and/or computer program products that provide physical vapor deposition with a dual-shutter are described.

According to an embodiment, a system can comprise a target plate, a first shutter plate, and a second shutter plate. The target plate can be associated with a voltage for physical vapor deposition. The first shutter plate can comprise a first set of openings. The second shutter plate can comprise a second set of openings. The first shutter plate and the second shutter plate can be located between the target plate and a substrate. The first shutter plate and the second shutter plate can rotate.

According to another embodiment, a computer-implemented method is provided. The computer-implemented method can comprise applying, by a system operatively coupled to a processor, a voltage to a target plate for physical vapor deposition. The computer-implemented method can also comprise rotating, by the system, a first shutter plate, that comprises a first set of openings and is located between the target plate and a substrate, at a first speed. Additionally, the computer-implemented method can comprise rotating, by the system, a second shutter plate, that comprises a second set of openings and is located between the target plate and the substrate, at a second speed.

According to yet another embodiment, a system can comprise a target plate, a first shutter plate, and a second shutter plate. The target plate can be associated with a voltage for physical vapor deposition. The first shutter plate can comprise a first set of openings. The second shutter plate can comprise a second set of openings. The first shutter plate and the second shutter plate can be located between the target plate and a substrate. The first shutter plate can rotate at a first speed. Furthermore, the second shutter plate can rotate at a second speed that is different than the first speed.

### DESCRIPTION OF THE DRAWINGS

FIG. 1 illustrates an example, non-limiting system associated with physical vapor deposition in accordance with one or more embodiments described herein.

FIG. 2 illustrates an example, non-limiting system associated with dual-shutters for physical vapor deposition in accordance with one or more embodiments described herein.

FIG. 3 illustrates another example, non-limiting system associated with dual-shutters for physical vapor deposition in accordance with one or more embodiments described herein.

FIG. 4 illustrates yet another example, non-limiting system associated with dual-shutters for physical vapor deposition in accordance with one or more embodiments described herein.

FIG. 5 illustrates yet another example, non-limiting system associated with dual-shutters for physical vapor deposition in accordance with one or more embodiments described herein.

FIG. 6 illustrates an example, non-limiting shutter plate in accordance with one or more embodiments described herein.

FIG. 7 illustrates another example, non-limiting system associated with physical vapor deposition in accordance with one or more embodiments described herein.

FIG. 8 illustrates a flow diagram of an example, non-limiting method that facilitates physical vapor deposition with a dual-shutter in accordance with one or more embodiments described herein.

FIG. 9 illustrates a flow diagram of an example, non-limiting method that facilitates physical vapor deposition with a dual-shutter in accordance with one or more embodiments described herein.

FIG. 10 illustrates a block diagram of an example, non-limiting operating environment in which one or more embodiments described herein can be facilitated.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Physical vapor deposition is a vacuum deposition technique that can be employed to deposit a film and/or a coating on a layer such as, for example, a substrate. For instance, with a physical vapor deposition process, a source material such as a solid or liquid can undergo evaporation and can be transformed into a gas phase. Furthermore, the gas phase can be transformed into a solid phase using, for example, a deposition process. In an aspect, a physical vapor deposition chamber can be employed to perform physical vapor deposition. The physical vapor deposition chamber generally comprises a target that provides the source material, a plasma to transport the gas phase, and a substrate layer where the film and/or coating is formed. However, it is often difficult to control a deposition rate of a film and/or a coating in a physical vapor deposition chamber. Therefore, a physical vapor deposition technique and/or a physical vapor deposition chamber can be improved.

Embodiments described herein include systems, computer-implemented methods, and computer program products that provide physical vapor deposition with a dual-shutter. A novel physical vapor deposition chamber design can be provided. The novel physical vapor deposition chamber can include at least two rotating shutters to provide improved control of a deposition rate of a film and/or a coating. The at least two rotating shutters can respectively include one or more openings. Furthermore, the at least two rotating shutters can be at least two shutter plates. In an aspect, the at least two rotating shutters can be located between a target plate and a substrate in the physical vapor deposition chamber. A voltage can be provided to the target plate to facilitate physical vapor deposition and/or to provide a source material. In another aspect, a deposition rate of a film and/or a coating can be controlled by adjusting relative position between the at least two rotating shutters. Additionally or alternatively, deposition rate of a film and/or a coating can be controlled by adjusting as size and/or a shape of the one or more openings associated with the at least two rotating shutters. Additionally or alternatively, deposition rate of a film and/or a coating can be controlled by modulating relative speed between the at least two rotating shutters. Additionally or alternatively, deposition rate of a film and/or a coating can be controlled by a direction of rotation for the at least two rotating shutters. As such, a deposition rate of a film and/or a coating deposited on a substrate within a physical vapor deposition chamber can be precisely controlled. Furthermore, performance and/or maintenance of a physical vapor deposition chamber can be improved. Quality of a film and/or a coating deposited on a substrate within a physical vapor deposition chamber can also be improved. Moreover, reduced thickness of a film and/or a coating deposited on a substrate within a physical vapor deposition chamber can be achieved. For example, a film and/or a coating thinner than 3 nm can be achieved.

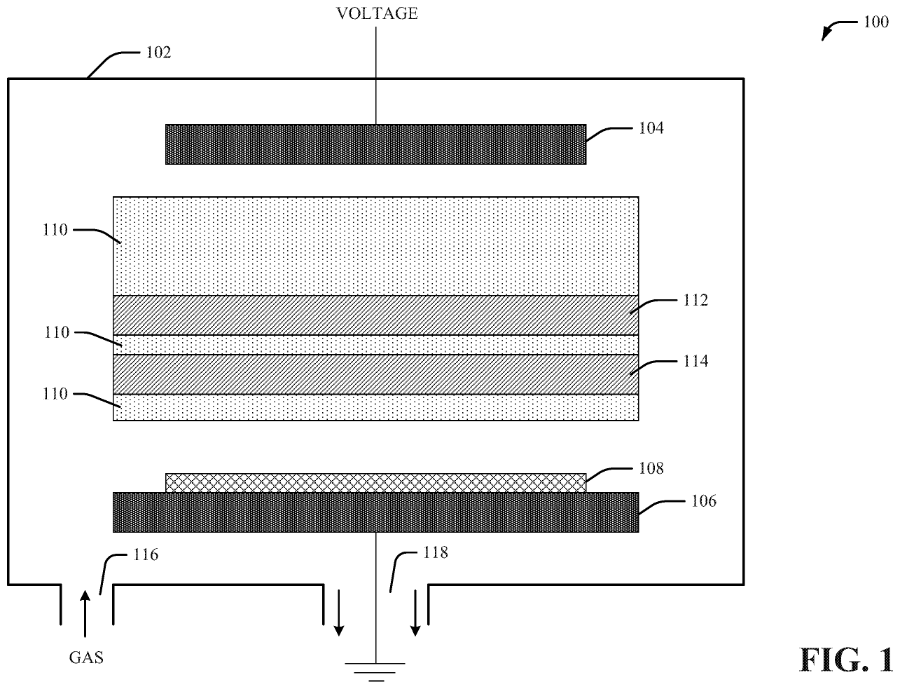

FIG. 1 illustrates an example, non-limiting system 100 in accordance with one or more embodiments described herein. In various embodiments, the system 100 can be a physical vapor deposition system associated with technologies such as, but not limited to, physical vapor deposition technologies, vacuum deposition technologies, physical vapor deposition chamber technologies, fabrication technologies, interconnect technologies, back end of line (BEOL) technologies, thin film technologies, coating technologies, semiconductor technologies, computer technologies, consumer electronics technologies, aerospace technologies, automotive technologies, material processing technologies, and/or other technologies. The system 100 can employ hardware and/or software to solve problems that are highly technical in nature, that are not abstract and that cannot be performed as a set of mental acts by a human. Further, some of the processes performed may be performed by one or more specialized computers (e.g., one or more specialized processing units, a specialized controller, etc.) for carrying out defined tasks related to physical vapor deposition. The system 100 and/or components of the system can be employed to solve new problems that arise through advancements in technologies mentioned above, employment of physical vapor deposition chamber systems, and/or computer architecture, and the like. One or more embodiments of the system 100 can provide technical improvements to physical vapor deposition systems, vacuum deposition systems, physical vapor deposition chamber systems, fabrication systems, interconnect systems, BEOL systems, thin film systems, coating systems, semiconductor systems, computer systems, consumer electronics systems, aerospace systems, automotive systems, material processing systems, and/or other technical systems. One or more embodiments of the system 100 can also provide technical improvements to a film and/or a coating associated with a physical vapor deposition process by improving quality of the film and/or coating, reducing thickness of the film and/or coating, etc. One or more embodiments of the system 100 can also provide technical improvements to a physical vapor deposition chamber by improving a deposition rate provided by the physical vapor deposition chamber.

In the embodiment shown in FIG. 1, the system 100 can include a physical vapor deposition chamber 102. The physical vapor deposition chamber 102 can include a target plate 104 and a substrate 106. The target plate 104 can be, for example, a metal plate. Furthermore, the substrate 106 can be, for example, a silicon wafer or a metal layer. In an aspect, a film 108 can be deposited on the substrate 106. The film 108 can be, for example, a thin film (e.g., a thin film material) with a thickness less than 3 nm. In another aspect, a plasma material 110 can be located between the target plate 104 and the substrate 106. The plasma material 110 can be, for example, a plasma that is formed in response to a voltage being applied to the target plate 104. In an aspect, the plasma material 110 can include a set of target atoms associated with a source material provided by the target plate 104.

In an embodiment, a shutter plate 112 and a shutter plate 114 can be located between the target plate 104 and the substrate 106. For instance, a surface of the shutter plate 112 and a surface of shutter plate 114 can be parallel to a surface of the target plate 104 and/or a surface of the substrate 106. In an aspect, the shutter plate 112 and the shutter plate 114 can be implemented as dual-shutters for physical vapor deposition. In another aspect, the shutter plate 112 and the shutter plate 114 can be surrounded by the plasma material 110. The shutter plate 112 can include a first set of openings. Furthermore, the shutter plate 114 can include a second set of openings. The first set of openings of the shutter plate 112 can include one or more openings. Furthermore, the second set of openings of the shutter plate 114 can include one or more openings. The shutter plate 112 and/or the shutter plate 114 can rotate. For instance, the shutter plate 112 can rotate at a first speed. Furthermore, the shutter plate 114 can rotate at a second speed. In an embodiment, the second speed can be different than the first speed. In another embodiment, the first speed can correspond to the second speed. In certain embodiments, the shutter plate 112 and the shutter plate 114 can rotate in a corresponding direction. For example, the shutter plate 112 and the shutter plate 114 can both rotate in a clockwise direction. In another example, the shutter plate 112 and the shutter plate 114 can both rotate in a counterclockwise direction. In another embodiment, the shutter plate 112 and the shutter plate 114 can rotate in opposite directions. For example, the shutter plate 112 can rotate in a clockwise direction and the shutter plate 114 can rotate in a counterclockwise direction. In another example, the shutter plate 112 can rotate in a counterclockwise direction and the shutter plate 114 can rotate in a clockwise direction. In an aspect, the film 108 can be deposited on the substrate 106 in response to alignment of the first set of openings of the shutter plate 112 and the second set of openings of the shutter plate 114. For example, deposition of material and/or a layer for the film 108 can occur in response to alignment of the first set of openings of the shutter plate 112 and the second set of openings of the shutter plate 114. In another aspect, deposition of the film 108 on the substrate 106 can be avoided in response to misalignment of the first set of openings of the shutter plate 112 and the second set of openings of the shutter plate 114. For example, deposition of material and/or a layer for the film 108 can be avoided in response to misalignment of the first set of openings of the shutter plate 112 and the second set of openings of the shutter plate 114.

In certain embodiments, the first speed associated with rotation of the shutter plate 112 and/or the second speed associated with rotation of the shutter plate 114 can be modulated to control a deposition rate of the film 108 on the substrate 106. For instance, alignment between the shutter plate 112 and the shutter plate 114 can be modulated through the first speed of the shutter plate 112 and the second speed of the shutter plate 112 to control a deposition rate of the film 108 on the substrate 106. In certain embodiments, a position between the first set of openings of the shutter plate 112 and the second set of openings of the shutter plate 114 can be adjusted to control a deposition rate of the film 108 on the substrate 106. In certain embodiments, a size of the first set of openings of the shutter plate 112 and/or a size of the second set of openings of the shutter plate 114 can be adjusted to control a deposition rate of the film 108 on the substrate 106. Additionally or alternatively, a shape of the first set of openings of the shutter plate 112 and/or a shape of the second set of openings of the shutter plate 114 can be adjusted to control a deposition rate of the film 108 on the substrate 106. As such, a rate of deposition of material and/or a layer for the film 108 can be precisely controlled based on rotation of the shutter plate 112 and the shutter plate 114. Additionally or alternatively, a rate of deposition of material and/or a layer for the film 108 can be precisely controlled based on location of the first set of openings of the shutter plate 112 with respect to the second set of openings of the shutter plate 114. In certain embodiments, the physical vapor deposition chamber 102 can include a gas inlet 116 to facilitate physical vapor deposition associated with deposition of the film 108 on the substrate 106. For example, a gas such as argon gas or another gas can enter the physical vapor deposition chamber 102 via the gas inlet 116. Furthermore, in certain embodiments, the physical vapor deposition chamber 102 can include a vacuum opening 118 to facilitate physical vapor deposition associated with deposition of the film 108 on the substrate 106. Additionally, in certain embodiments, the substrate 106 can be electrically grounded to facilitate physical vapor deposition associated with deposition of the film 108 on the substrate 106.

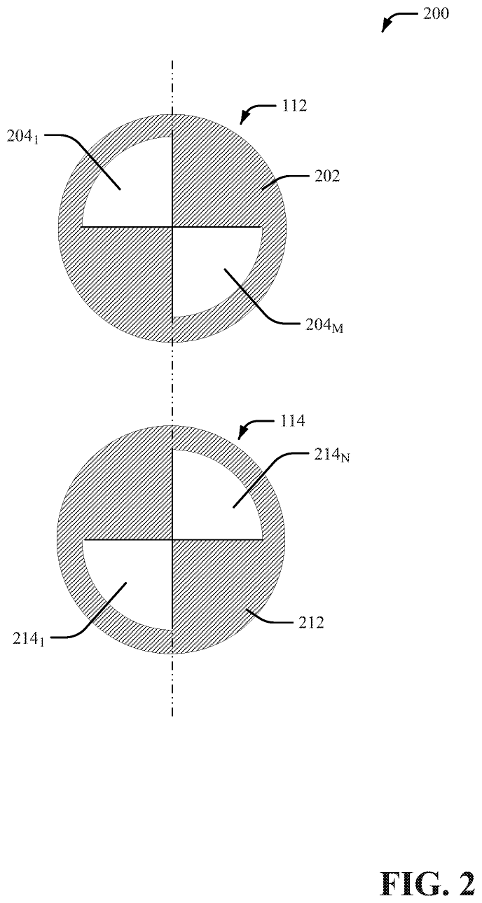

FIG. 2 illustrates an example, non-limiting system 200 in accordance with one or more embodiments described herein. Repetitive description of like elements employed in other embodiments described herein is omitted for sake of brevity.

The system 200 includes the shutter plate 112 and the shutter plate 114. The shutter plate 112 and the shutter plate 114 can be implemented as dual-shutters for physical vapor deposition. The shutter plate 112 includes a surface 202 and a set of openings 204_{1-M}, where M is an integer. The surface 202 of the shutter plate 112 can be a flat surface. Furthermore, in an embodiment, the surface 202 of the shutter plate 112 can be a metal material. In an alternate embodiment, the surface 202 of the shutter plate 112 can be a plastic material. The set of openings 204_{1-M} can include one or more openings. Furthermore, a size and/or a shape of the set of openings 204_{1-M} can be varied based on design implementation of the physical vapor deposition chamber 102 to, for example, achieve a particular deposition rate for the film 108 on the substrate 106. The shutter plate 112 includes a surface 212 and a set of openings 214_{1-N}, where N is an integer. The surface 212 of the shutter plate 114 can be a flat surface. Furthermore, in an embodiment, the surface 212 of the shutter plate 114 can be a metal material. In an alternate embodiment, the surface 212 of the shutter plate 114 can be a plastic material. The set of openings 214_{1-N} can include one or more openings. Furthermore, a size and/or a shape of the set of openings 214_{1-N} can be varied based on design implementation of the physical vapor deposition chamber 102 to, for example, achieve a particular deposition rate for the film 108 on the substrate 106. In an aspect, the shutter plate 112 can be implemented in parallel to the shutter plate 114. For instance, the surface 212 of the shutter plate 114 can be in parallel to a surface of the shutter plate 112 that is opposite to the surface 202. In certain embodiments, a number of the set of openings 204_{1-M} can correspond to a number of the set of openings 214_{1-N}. Alternatively, a number of the set of openings 204_{1-M} can be different than a number of the set of openings 214_{1-N}. In certain embodiments, a size of the set of openings 204_{1-M} can correspond to a size of the set of openings 214_{1-N}. Alternatively, one or more openings from the set of openings 204_{1-M} can comprise a different size than one or more openings of the set of openings 214_{1-N}. In certain embodiments, a shape of the set of openings 204_{1-M} can correspond to a shape of the set of openings 214_{1-N}. Alternatively, one or more openings from the set of openings 204_{1-M} can comprise a different shape than one or more openings of the set of openings 214_{1-N}. In an embodiment, alignment between the set of openings 204_{1-M} of the shutter plate 112 and the set of openings 214_{1-N} of the shutter plate 114 can be modulated to control a deposition rate of the film 108 on the substrate 106.

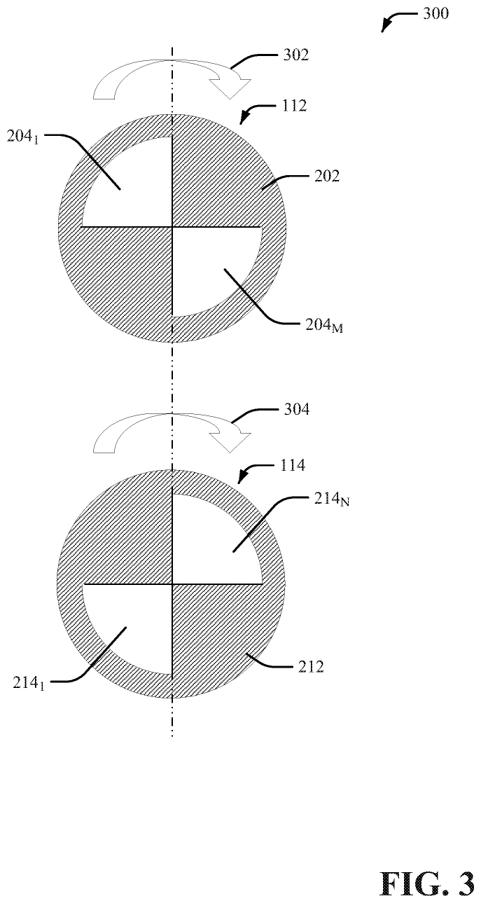

FIG. 3 illustrates an example, non-limiting system 300 in accordance with one or more embodiments described herein. Repetitive description of like elements employed in other embodiments described herein is omitted for sake of brevity.

The system 300 includes the shutter plate 112 and the shutter plate 114. The shutter plate 112 includes the surface 202 and the set of openings 204_{1-M}. The shutter plate 114 includes the surface 212 and the set of openings 214_{1-N}. The shutter plate 112 and the shutter plate 114 can be implemented as dual-shutters for physical vapor deposition. In an aspect, the shutter plate 112 can rotate in a first direction 302 and the shutter plate 114 can rotate in a second direction 304. For instance, the first direction 302 associated with rotation of the shutter plate 112 can correspond to the second direction 304 associated with rotation of the shutter plate 114. In one example, the first direction 302 associated with rotation of the shutter plate 112 and the second direction 304 associated with rotation of the shutter plate 114 can correspond to a clockwise direction. In another example, the first direction 302 associated with rotation of the shutter plate 112 and the second direction 304 associated with rotation of the shutter plate 114 can correspond to a counterclockwise direction. In another aspect, the shutter plate 112 can rotate in the first direction 302 at a first speed. Furthermore, the shutter plate 114 can rotate in the second direction 304 at a second speed. In an embodiment, the first speed associated with rotation of the shutter plate 112 in the first direction 302 can be different than the second speed associated with rotation of the shutter plate 114 in the second direction 304. In an alternate embodiment, the first speed associated with rotation of the shutter plate 112 in the first direction 302 can correspond to the second speed associated with rotation of the shutter plate 114 in the second direction 304. In yet another aspect, a position between the set of openings 204_{1-M} of the shutter plate 112 and the set of openings 204_{1-M} of the shutter plate 114 can be adjusted to control a deposition rate of the film 108 on the substrate 106. In an embodiment, the first speed of the shutter plate 112 in the first direction 302 and/or the second speed of the shutter plate 114 in the second direction 304 can be modulated to, for example, control a deposition rate of the film 108 on the substrate 106. In another embodiment, the first direction 302 associated with rotation of the shutter plate 112 and/or the second direction 304 associated with rotation of the shutter plate 114 can be altered to, for example, control a deposition rate of the film 108 on the substrate 106.

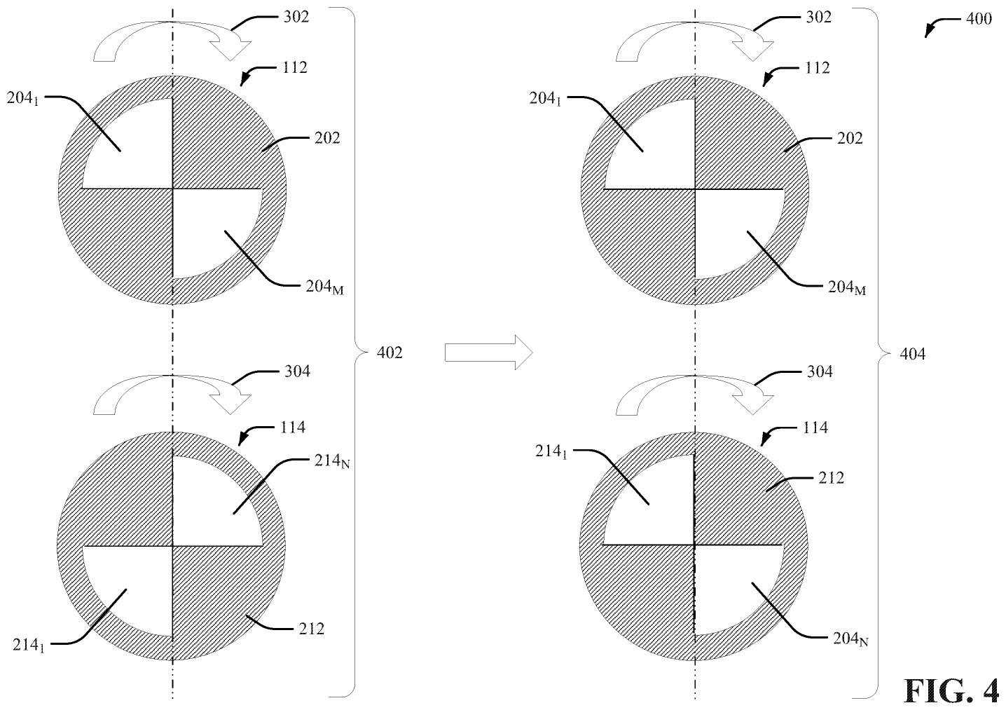

FIG. 4 illustrates an example, non-limiting system 400 in accordance with one or more embodiments described herein. Repetitive description of like elements employed in other embodiments described herein is omitted for sake of brevity.

The system 400 includes the shutter plate 112 and the shutter plate 114. The shutter plate 112 includes the surface 202 and the set of openings 204_{1-M}. The shutter plate 114 includes the surface 212 and the set of openings 214_{1-N}. The shutter plate 112 and the shutter plate 114 can be implemented as dual-shutters for physical vapor deposition. In an aspect, the shutter plate 112 can rotate in the first direction 302 and the shutter plate 114 can rotate in the second direction 304. The system 400 illustrates a dual shutter plate arrangement 402 and a dual shutter plate arrangement 404. With the dual shutter plate arrangement 402, the set of openings 204_{1-M} of the shutter plate 112 can be misaligned with respect to the set of openings 214_{1-N} of the shutter plate 114. For example, with the dual shutter plate arrangement 402, the opening 204₁ of the shutter plate 112 can be misaligned with respect to the opening 214₁ and the 214_{N} of the shutter plate 114. Furthermore, with the dual shutter plate arrangement 402, the opening 204M of the shutter plate 112 can be misaligned with respect to the opening 214₁ and the 214_{N} of the shutter plate 114. Therefore, with the dual shutter plate arrangement 402, deposition of material and/or a layer for the film 108 onto the substrate 106 can be avoided. In contrast, with the dual shutter plate arrangement 404, the set of openings 204_{1-M} of the shutter plate 112 can aligned with the set of openings 214_{1-N} of the shutter plate 114. For example, with the dual shutter plate arrangement 404, the opening 204₁ of the shutter plate 112 can be aligned with the opening 214₁ of the shutter plate 114. Furthermore, with the dual shutter plate arrangement 404, the opening 204M of the shutter plate 112 can be aligned with the opening 214_{N} of the shutter plate 114. As such, with the dual shutter plate arrangement 404, material and/or a layer for the film 108 can be deposited onto the substrate 106. In certain embodiments, the dual shutter plate arrangement 402 can be altered to the dual shutter plate arrangement 404 based on different rotational speeds of the shutter plate 112 and the shutter plate 114.

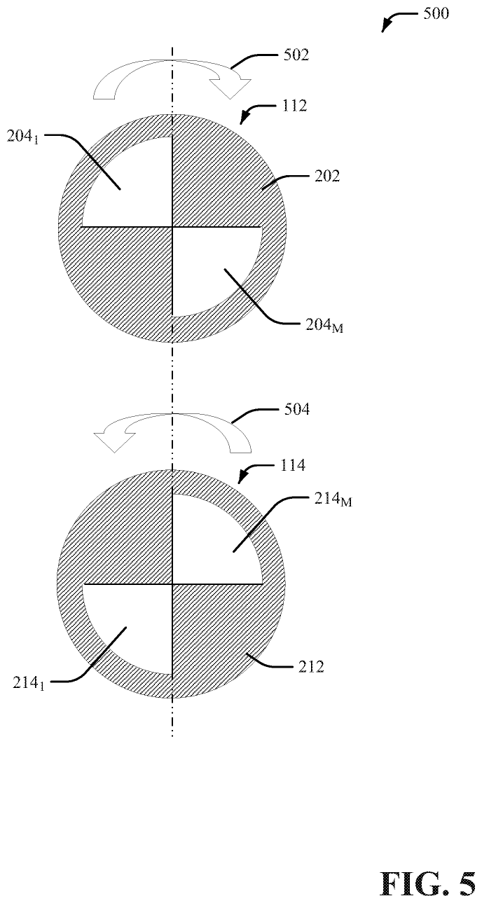

FIG. 5 illustrates an example, non-limiting system 500 in accordance with one or more embodiments described herein. Repetitive description of like elements employed in other embodiments described herein is omitted for sake of brevity.

The system 500 includes the shutter plate 112 and the shutter plate 114. The shutter plate 112 includes the surface 202 and the set of openings 204_{1-M}. The shutter plate 114 includes the surface 212 and the set of openings 214_{1-N}. The shutter plate 112 and the shutter plate 114 can be implemented as dual-shutters for physical vapor deposition. In an aspect, the shutter plate 112 can rotate in a first direction 502 and the shutter plate 114 can rotate in a second direction 504. For instance, the first direction 502 associated with rotation of the shutter plate 112 can be different than the second direction 504 associated with rotation of the shutter plate 114. In one example, the first direction 502 associated with rotation of the shutter plate 112 can correspond to a clockwise direction and the second direction 504 associated with rotation of the shutter plate 114 can correspond to a counterclockwise direction. In another example, the first direction 502 associated with rotation of the shutter plate 112 can correspond to a counterclockwise direction and the second direction 504 associated with rotation of the shutter plate 114 can correspond to a clockwise direction. In another aspect, the shutter plate 112 can rotate in the first direction 502 at a first speed. Furthermore, the shutter plate 114 can rotate in the second direction 504 at a second speed. In an embodiment, the first speed associated with rotation of the shutter plate 112 in the first direction 502 can be different than the second speed associated with rotation of the shutter plate 114 in the second direction 504. In an alternate embodiment, the first speed associated with rotation of the shutter plate 112 in the first direction 502 can correspond to the second speed associated with rotation of the shutter plate 114 in the second direction 504. In yet another aspect, a position between the set of openings 204_{1-M} of the shutter plate 112 and the set of openings 204_{1-M} of the shutter plate 114 can be adjusted to control a deposition rate of the film 108 on the substrate 106. In an embodiment, the first speed of the shutter plate 112 in the first direction 502 and/or the second speed of the shutter plate 114 in the second direction 504 can be modulated to, for example, control a deposition rate of the film 108 on the substrate 106. In another embodiment, the first direction 502 associated with rotation of the shutter plate 112 and/or the second direction 504 associated with rotation of the shutter plate 114 can be altered to, for example, control a deposition rate of the film 108 on the substrate 106.

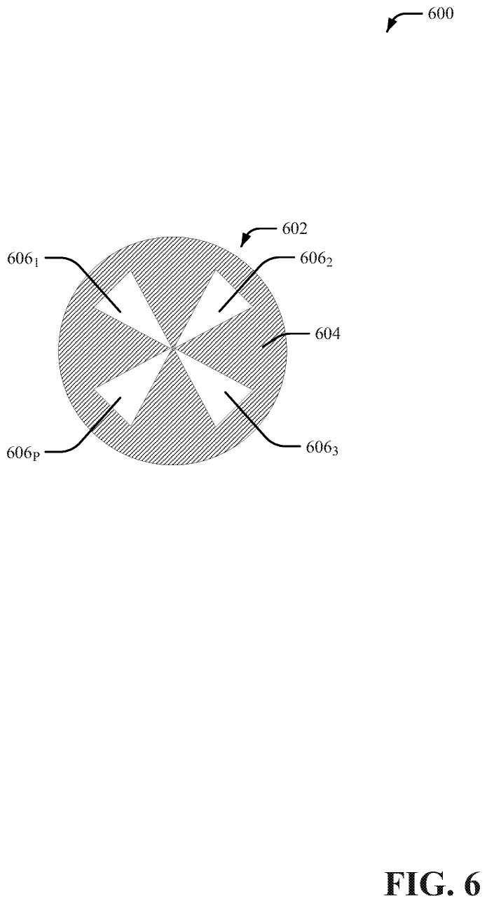

FIG. 6 illustrates an example, non-limiting system 600 in accordance with one or more embodiments described herein. Repetitive description of like elements employed in other embodiments described herein is omitted for sake of brevity.

The system 600 includes a shutter plate 602. The shutter plate 602 can correspond to an alternate embodiment of the shutter plate 112 and/or the shutter plate 114. The shutter plate 602 can be implemented as a shutter for physical vapor deposition. The shutter plate 602 includes a surface 604 and a set of openings 606_{1-P}, where P is an integer. The surface 604 of the shutter plate 602 can be a flat surface. Furthermore, in an embodiment, the surface 604 of the shutter plate 602 can be a metal material. In an alternate embodiment, the surface 604 of the shutter plate 602 can be a plastic material. The set of openings 606_{1-P} can include, for example, four openings or another number of openings. Furthermore, a size and/or a shape of the set of openings 606_{1-P} can be varied based on design implementation of the physical vapor deposition chamber 102 to, for example, achieve a particular deposition rate for the film 108 on the substrate 106.

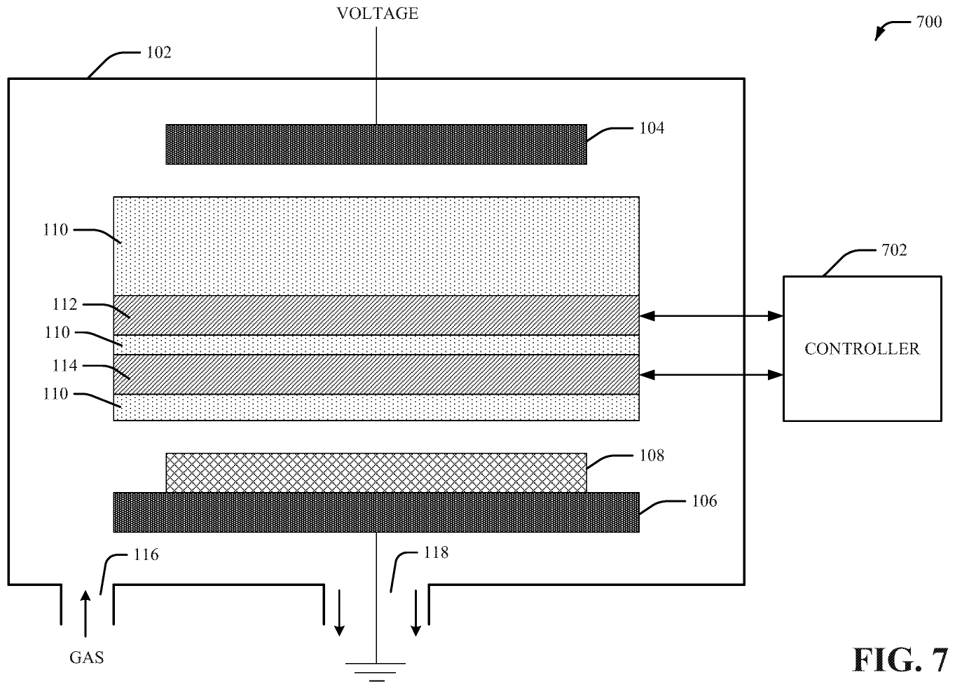

FIG. 7 illustrates an example, non-limiting system 700 in accordance with one or more embodiments described herein. Repetitive description of like elements employed in other embodiments described herein is omitted for sake of brevity.

The system 700 includes the physical vapor deposition chamber 102 and a controller 702. In an embodiment, the controller 702 can be implemented external from the physical vapor deposition chamber 102. In another embodiment, the physical vapor deposition chamber 102 can include the controller 702. The physical vapor deposition chamber 102 can include the target plate 104, the substrate 106, the film 108, the plasma material 110, the shutter plate 112 and the shutter plate 114. The shutter plate 112 and the shutter plate 114 can be implemented as dual-shutters for physical vapor deposition. In certain embodiments, the physical vapor deposition chamber 102 can include the gas inlet 116 and/or the vacuum opening 118. The controller 702 can include hardware and/or software to facilitate control of the shutter plate 112 and/or the shutter plate 114. The controller 702 can be communicatively coupled to the shutter plate 112 and/or the shutter plate 114. In an embodiment, the controller 702 can be a single controller that controls the shutter plate 112 and the shutter plate 114. In another embodiment, the controller 702 can include a first controller to control the shutter plate 112 and a second controller to control the shutter plate 114. In certain embodiments, aspects of the controller 702 can constitute machine-executable component(s) embodied within machine(s), e.g., embodied in one or more computer readable mediums (or media) associated with one or more machines. Such component(s), when executed by the one or more machines, e.g., computer(s), computing device(s), virtual machine(s), etc. can cause the machine(s) to perform the operations described. In an aspect, the controller 702 can also include a memory (not shown in FIG. 7) that stores computer executable components and instructions. Furthermore, the controller 702 can include a processor (not shown in FIG. 7) to facilitate execution of the instructions (e.g., computer executable components and corresponding instructions) by the controller 702.

In an aspect, the controller 702 can control rotation of the shutter plate 112 and/or the shutter plate 114. For instance, the controller 702 can control the shutter plate 112 to rotate at a first speed. Furthermore, the controller 702 can control the shutter plate 114 to rotate at a second speed. For example, in an embodiment, the controller 702 can control the shutter plate 114 to rotate at the second speed that is different than the first speed. In another embodiment, the controller 702 can control the shutter plate 112 and the shutter plate 114 to rotate at the same speed. In certain embodiments, the controller 702 can control the shutter plate 112 and the shutter plate 114 to rotate in a corresponding direction. For example, the controller 702 can control the shutter plate 112 and the shutter plate 114 to both rotate in a clockwise direction. In another example, the controller 702 can control the shutter plate 112 and the shutter plate 114 to both rotate in a counterclockwise direction. In another embodiment, the controller 702 can control the shutter plate 112 and the shutter plate 114 to rotate in opposite directions. For example, the controller 702 can control the shutter plate 112 to rotate in a clockwise direction. Furthermore, the controller 702 can control the shutter plate 114 to rotate in a counterclockwise direction. In another example, the controller 702 can control the shutter plate 112 to rotate in a counterclockwise direction. Furthermore, the controller 702 can control the shutter plate 114 to rotate in a clockwise direction. In certain embodiments, the controller 702 can modulate the first speed associated with rotation of the shutter plate 112 and/or the second speed associated with rotation of the shutter plate 114 to control a deposition rate of the film 108 on the substrate 106. In certain embodiments, the controller 702 can adjust a position between the first set of openings of the shutter plate 112 and the second set of openings of the shutter plate 114 to control a deposition rate of the film 108 on the substrate 106. In certain embodiments, the controller 702 can repeatedly modulate the first speed of the first shutter plate and/or the second speed of the second shutter plate during an interval of time to control a deposition rate of a film on the substrate. In certain embodiments, the controller 702 can repeatedly control direction of rotation of the first shutter plate and/or the second shutter plate during an interval of time to control a deposition rate of a film on the substrate. As such, a rate of deposition of material and/or a layer for the film 108 can be precisely controlled based control of rotation of the shutter plate 112 and the shutter plate 114 by the controller 702. Additionally or alternatively, a rate of deposition of material and/or a layer for the film 108 can be precisely controlled based on control of a location of the first set of openings of the shutter plate 112 with respect to the second set of openings of the shutter plate 114 by the controller 702.

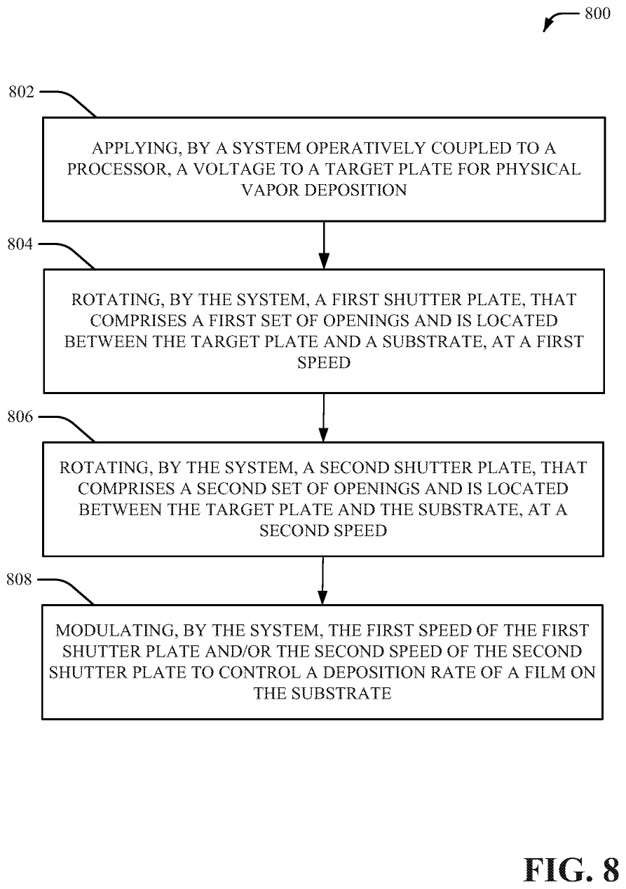

FIG. 8 illustrates a flow diagram of an example, non-limiting computer-implemented method 800 that facilitates physical vapor deposition with a dual-shutter in accordance with one or more embodiments described herein. Repetitive description of like elements employed in other embodiments described herein is omitted for sake of brevity. At 802, a voltage is applied, by a system operatively coupled to a processor (e.g., by controller 702), to a target plate for physical vapor deposition. For example, a power source can apply a voltage (e.g., a negative voltage) to the target plate to facilitate physical vapor deposition within a physical vapor deposition chamber. The target plate can be located within the physical vapor deposition chamber. Furthermore, the target plate can be, for example, a metal plate. In an aspect, the voltage can be applied to the target plate to facilitate vaporization of a source material (e.g., a liquid or a metal) provided by the target plate.

At 804, a first shutter plate, that comprises a first set of openings and is located between the target plate and a substrate, is rotated, by the system (e.g., by controller 702), at a first speed. For example, the first shutter plate can be rotated in a clockwise direction parallel to the target plate and the substrate. In another example, the first shutter plate can be rotated in a counterclockwise direction parallel to the target plate and the substrate.

At 806, a second shutter plate, that comprises a second set of openings and is located between the target plate and the substrate, is rotated, by the system (e.g., by controller 702), at a second speed. For example, the second shutter plate can be rotated in a clockwise direction parallel to the target plate and the substrate. In another example, the second shutter plate can be rotated in a counterclockwise direction parallel to the target plate, the substrate and the first shutter plate.

At 808, the first speed of the first shutter plate and/or the second speed of the second shutter plate is modulated, by the system (e.g., by controller 702), to control a deposition rate of a film on the substrate. For example, the first speed of the first shutter plate and/or the second speed of the second shutter plate can be increased to control a deposition rate of a film on the substrate. Additionally or alternatively, the first speed of the first shutter plate and/or the second speed of the second shutter plate can be decreased to control a deposition rate of a film on the substrate. In certain embodiments, the first speed of the first shutter plate and/or the second speed of the second shutter plate can be repeatedly modulated during an interval of time to control a deposition rate of a film on the substrate. In certain embodiments, the computer-implemented method 800 can additionally or alternatively include adjusting, a position between the first set of openings and the second set of openings to control a deposition rate of a film on the substrate. In certain embodiments, the computer-implemented method 800 can additionally or alternatively include controlling a deposition rate of a film on the substrate based on a shape of the first set of openings and/or a shape of the second set of openings. In certain embodiments, the computer-implemented method 800 can additionally or alternatively include controlling a deposition rate of a film on the substrate based on a size of the first set of openings and/or a size the second set of openings. In certain embodiments, the computer-implemented method 800 can additionally or alternatively include adjusting direction of rotation of the first shutter plate and/or direction of rotation of the second shutter plate to control a deposition rate of a film on the substrate.

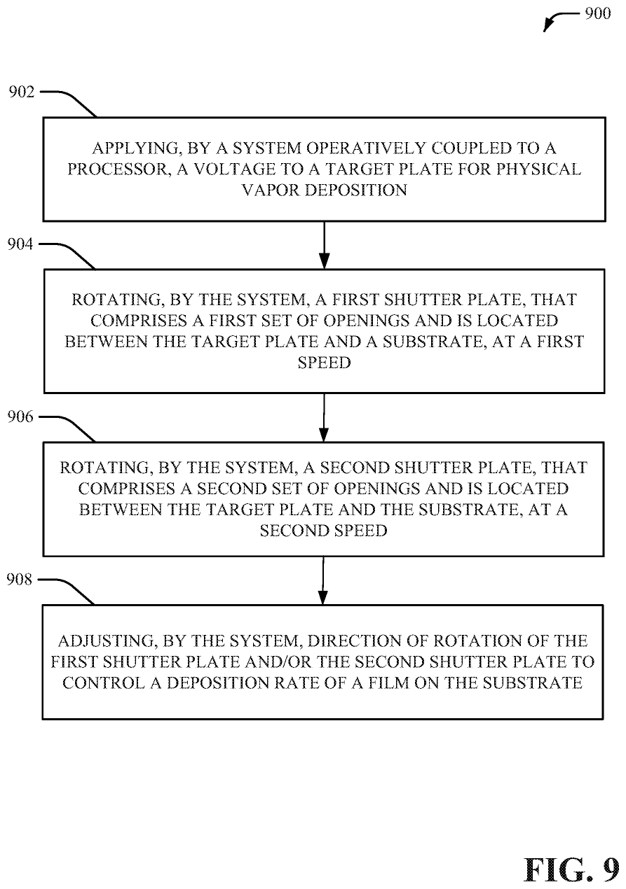

FIG. 9 illustrates a flow diagram of an example, non-limiting computer-implemented method 900 that facilitates physical vapor deposition with a dual-shutter in accordance with one or more embodiments described herein. Repetitive description of like elements employed in other embodiments described herein is omitted for sake of brevity. At 902, a voltage is applied, by a system operatively coupled to a processor (e.g., by controller 702), to a target plate for physical vapor deposition. For example, a power source can apply a voltage (e.g., a negative voltage) to the target plate to facilitate physical vapor deposition within a physical vapor deposition chamber. The target plate can be located within the physical vapor deposition chamber. Furthermore, the target plate can be, for example, a metal plate. In an aspect, the voltage can be applied to the target plate to facilitate vaporization of a source material (e.g., a liquid or a metal) provided by the target plate.

At 904, a first shutter plate, that comprises a first set of openings and is located between the target plate and a substrate, is rotated, by the system (e.g., by controller 702), at a first speed. For example, the first shutter plate can be rotated in a clockwise direction parallel to the target plate and the substrate. In another example, the first shutter plate can be rotated in a counterclockwise direction parallel to the target plate and the substrate.

At 906, a second shutter plate, that comprises a second set of openings and is located between the target plate and the substrate, is rotated, by the system (e.g., by controller 702), at a second speed. For example, the second shutter plate can be rotated in a clockwise direction parallel to the target plate and the substrate. In another example, the second shutter plate can be rotated in a counterclockwise direction parallel to the target plate, the substrate and the first shutter plate.

At 908, direction of rotation of the first shutter plate and/or the second shutter plate is adjusted, by the system (e.g., by controller 702), to control a deposition rate of a film on the substrate. For example, direction of rotation of the first shutter plate and/or the second shutter plate can be altered to a clockwise direction. Additionally or alternatively, direction of rotation of the first shutter plate and/or the second shutter plate can be altered to a counterclockwise direction. In certain embodiments, direction of rotation of the first shutter plate and/or the second shutter plate can be repeatedly adjusted during an interval of time to control a deposition rate of a film on the substrate. In certain embodiments, the computer-implemented method 900 can additionally or alternatively include adjusting, a position between the first set of openings and the second set of openings to control a deposition rate of a film on the substrate. In certain embodiments, the computer-implemented method 900 can additionally or alternatively include controlling a deposition rate of a film on the substrate based on a shape of the first set of openings and/or a shape of the second set of openings. In certain embodiments, the computer-implemented method 900 can additionally or alternatively include controlling a deposition rate of a film on the substrate based on a size of the first set of openings and/or a size the second set of openings. In certain embodiments, the computer-implemented method 900 can additionally or alternatively include adjusting direction of rotation of the first shutter plate and/or direction of rotation of the second shutter plate to control a deposition rate of a film on the substrate. In certain embodiments, the computer-implemented method 900 can additionally or alternatively include modulating the first speed of the first shutter plate and the second speed of the second shutter plate to control a deposition rate of a film on the substrate. For example, the first speed of the first shutter plate and/or the second speed of the second shutter plate can be increased to control a deposition rate of a film on the substrate. Additionally or alternatively, the first speed of the first shutter plate and/or the second speed of the second shutter plate can be decreased to control a deposition rate of a film on the substrate. In certain embodiments, the computer-implemented method 900 can additionally or alternatively include modulating alignment between the first shutter plate and the second shutter plate through the first speed of the first shutter plate and the second speed of the second shutter plate to control a deposition rate of a film on the substrate.

For simplicity of explanation, the computer-implemented methodologies are depicted and described as a series of acts. It is to be understood and appreciated that the subject innovation is not limited by the acts illustrated and/or by the order of acts, for example acts can occur in various orders and/or concurrently, and with other acts not presented and described herein. Furthermore, not all illustrated acts can be required to implement the computer-implemented methodologies in accordance with the disclosed subject matter. In addition, those skilled in the art will understand and appreciate that the computer-implemented methodologies could alternatively be represented as a series of interrelated states via a state diagram or events. Additionally, it should be further appreciated that the computer-implemented methodologies disclosed hereinafter and throughout this specification are capable of being stored on an article of manufacture to facilitate transporting and transferring such computer-implemented methodologies to computers. The term article of manufacture, as used herein, is intended to encompass a computer program accessible from any computer-readable device or storage media.

Moreover, because at least applying a voltage to a target plate, rotating a first shutter plate, rotating a second shutter plate, adjusting direction of rotation of a first shutter plate and/or a second shutter plate, and/or modulating speed of a first shutter plate and/or a second shutter plate is established from a combination of electrical and mechanical components and circuitry, a human is unable to replicate or perform processing performed by the controller 702 disclosed herein.

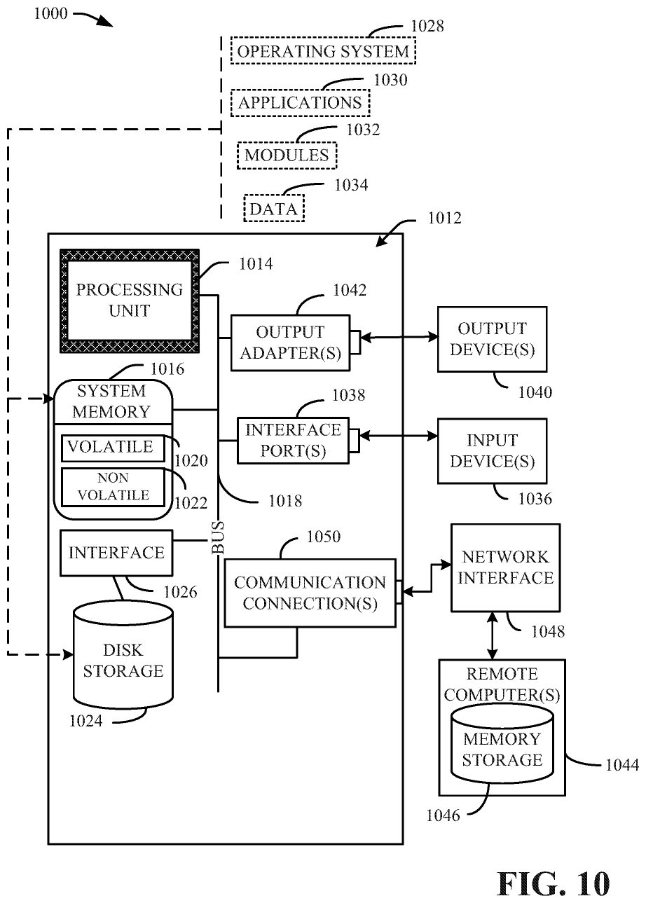

In order to provide a context for the various aspects of the disclosed subject matter, FIG. 10 as well as the following discussion are intended to provide a general description of a suitable environment in which the various aspects of the disclosed subject matter can be implemented. FIG. 10 illustrates a block diagram of an example, non-limiting operating environment in which one or more embodiments described herein can be facilitated. Repetitive description of like elements employed in other embodiments described herein is omitted for sake of brevity.

With reference to FIG. 10, a suitable operating environment 1000 for implementing various aspects of this disclosure can also include a computer 1012. The computer 1012 can also include a processing unit 1014, a system memory 1016, and a system bus 1018. The system bus 1018 couples system components including, but not limited to, the system memory 1016 to the processing unit 1014. The processing unit 1014 can be any of various available processors. Dual microprocessors and other multiprocessor architectures also can be employed as the processing unit 1014. The system bus 1018 can be any of several types of bus structure(s) including the memory bus or memory controller, a peripheral bus or external bus, and/or a local bus using any variety of available bus architectures including, but not limited to, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Card Bus, Universal Serial Bus (USB), Advanced Graphics Port (AGP), Firewire (IEEE 1394), and Small Computer Systems Interface (SCSI).

The system memory 1016 can also include volatile memory 1020 and nonvolatile memory 1022. The basic input/output system (BIOS), containing the basic routines to transfer information between elements within the computer 1012, such as during start-up, is stored in nonvolatile memory 1022. Computer 1012 can also include removable/non-removable, volatile/non-volatile computer storage media. FIG. 10 illustrates, for example, a disk storage 1024. Disk storage 1024 can also include, but is not limited to, devices like a magnetic disk drive, floppy disk drive, tape drive, Jaz drive, Zip drive, LS-100 drive, flash memory card, or memory stick. The disk storage 1024 also can include storage media separately or in combination with other storage media. To facilitate connection of the disk storage 1024 to the system bus 1018, a removable or non-removable interface is typically used, such as interface 1026. FIG. 10 also depicts software that acts as an intermediary between users and the basic computer resources described in the suitable operating environment 1000. Such software can also include, for example, an operating system 1028. Operating system 1028, which can be stored on disk storage 1024, acts to control and allocate resources of the computer 1012.

System applications 1030 take advantage of the management of resources by operating system 1028 through program modules 1032 and program data 1034, e.g., stored either in system memory 1016 or on disk storage 1024. It is to be appreciated that this disclosure can be implemented with various operating systems or combinations of operating systems. A user enters commands or information into the computer 1012 through input device(s) 1036. Input devices 1036 include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices connect to the processing unit 1014 through the system bus 1018 via interface port(s) 1038. Interface port(s) 1038 include, for example, a serial port, a parallel port, a game port, and a universal serial bus (USB). Output device(s) 1040 use some of the same type of ports as input device(s) 1036. Thus, for example, a USB port can be used to provide input to computer 1012, and to output information from computer 1012 to an output device 1040. Output adapter 1042 is provided to illustrate that there are some output devices 1040 like monitors, speakers, and printers, among other output devices 1040, which require special adapters. The output adapters 1042 include, by way of illustration and not limitation, video and sound cards that provide a means of connection between the output device 1040 and the system bus 1018. It should be noted that other devices and/or systems of devices provide both input and output capabilities such as remote computer(s) 1044.

Computer 1012 can operate in a networked environment using logical connections to one or more remote computers, such as remote computer(s) 1044. The remote computer(s) 1044 can be a computer, a server, a router, a network PC, a workstation, a microprocessor based appliance, a peer device or other common network node and the like, and typically can also include many or all of the elements described relative to computer 1012. For purposes of brevity, only a memory storage device 1046 is illustrated with remote computer(s) 1044. Remote computer(s) 1044 is logically connected to computer 1012 through a network interface 1048 and then physically connected via communication connection 1050. Network interface 1048 encompasses wire and/or wireless communication networks such as local-area networks (LAN), wide-area networks (WAN), cellular networks, etc. LAN technologies include Fiber Distributed Data Interface (FDDI), Copper Distributed Data Interface (CDDI), Ethernet, Token Ring and the like. WAN technologies include, but are not limited to, point-to-point links, circuit switching networks like Integrated Services Digital Networks (ISDN) and variations thereon, packet switching networks, and Digital Subscriber Lines (DSL). Communication connection(s) 1050 refers to the hardware/software employed to connect the network interface 1048 to the system bus 1018. While communication connection 1050 is shown for illustrative clarity inside computer 1012, it can also be external to computer 1012. The hardware/software for connection to the network interface 1048 can also include, for exemplary purposes only, internal and external technologies such as, modems including regular telephone grade modems, cable modems and DSL modems, ISDN adapters, and Ethernet cards.

The present invention may be a system, a method, an apparatus and/or a computer program product at any possible technical detail level of integration. The computer program product can include a computer readable storage medium (or media) having computer readable program instructions thereon for causing a processor to carry out aspects of the present invention. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the present invention can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some embodiments, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions. These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions can also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks. The computer readable program instructions can also be loaded onto a computer, other programmable data processing apparatus, or other device to cause a series of operational acts to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams can represent a module, segment, or portion of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the subject matter has been described above in the general context of computer-executable instructions of a computer program product that runs on a computer and/or computers, those skilled in the art will recognize that this disclosure also can or can be implemented in combination with other program modules. Generally, program modules include routines, programs, components, data structures, etc. that perform particular tasks and/or implement particular abstract data types. Moreover, those skilled in the art will appreciate that the inventive computer-implemented methods can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics, and the like. The illustrated aspects can also be practiced in distributed computing environments in which tasks are performed by remote processing devices that are linked through a communications network. However, some, if not all aspects of this disclosure can be practiced on stand-alone computers. In a distributed computing environment, program modules can be located in both local and remote memory storage devices.

As used in this application, the terms “component,” “system,” “platform,” “interface,” and the like, can refer to and/or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program, and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, wherein the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units. In this disclosure, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory and/or memory components described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, or nonvolatile random access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM (RDRAM). Additionally, the disclosed memory components of systems or computer-implemented methods herein are intended to include, without being limited to including, these and any other suitable types of memory.

What has been described above include mere examples of systems and computer-implemented methods. It is, of course, not possible to describe every conceivable combination of components or computer-implemented methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A system, comprising:
a target plate associated with a voltage for physical vapor deposition;
a first shutter plate that comprises a first set of openings; and
a second shutter plate that comprises a second set of openings, wherein the first shutter plate and the second shutter plate are located between the target plate and a substrate, and wherein the first shutter plate and the second shutter rotate.

2. The system of claim 1, wherein the first shutter plate rotates at a first speed and the second shutter plate rotates at a second speed that is different than the first speed.

3. The system of claim 1, wherein the first shutter plate and the second shutter plate rotate in a corresponding direction.

4. The system of claim 1, wherein the first shutter plate and the second shutter plate rotate in opposite directions.

5. The system of claim 1, wherein a film is deposited on the substrate in response to alignment of the first set of openings and the second set of openings.

6. The system of claim 1, wherein a film is not deposited on the substrate in response to misalignment of the first set of openings and the second set of openings.

7. The system of claim 1, wherein the system is a physical vapor deposition chamber that comprises the target plate, the first shutter plate, the second shutter plate and the substrate.

8. The system of claim 1, wherein the first shutter plate and the second shutter plate rotate to improve quality of a film deposited on the substrate.

9. A computer-implemented method, comprising:
applying, by a system operatively coupled to a processor, a voltage to a target plate for physical vapor deposition;
rotating, by the system, a first shutter plate, that comprises a first set of openings and is located between the target plate and a substrate, at a first speed; and
rotating, by the system, a second shutter plate, that comprises a second set of openings and is located between the target plate and the substrate, at a second speed.

10. The method of claim 9, further comprising:
modulating, by the system, alignment between the first shutter plate and the second shutter plate through the first speed of the first shutter plate and the second speed of the second shutter plate to control a deposition rate of a film on the substrate.

11. The method of claim 9, further comprising:
adjusting, by the system, a position between the first set of openings and the second set of openings to control a deposition rate of a film on the substrate.

12. The method of claim 9, further comprising:
controlling, by the system, a deposition rate of a film on the substrate based on a shape of the first set of openings and the second set of openings.

13. The method of claim 9, further comprising:
controlling, by the system, a deposition rate of a film on the substrate based on a size of the first set of openings and the second set of openings.

14. The method of claim 9, further comprising:
adjusting, by the system, direction of rotation of the first shutter plate and the second shutter plate to control a deposition rate of a film on the substrate.

15. The method of claim 9, wherein the rotating the first shutter plate comprises rotating the first shutter plate in a first direction, and wherein the rotating the second shutter plate comprises rotating the second shutter plate in a second direction that is different than the first direction.

16. The method of claim 9, wherein the rotating the first shutter plate comprises rotating the first shutter plate in a first direction, and wherein the rotating the second shutter plate comprises rotating the second shutter plate in a second direction that corresponds to the first direction.

17. The method of claim 9, wherein the rotating the second shutter plate comprises improving quality of a film deposited on the substrate.

18. A system, comprising:
a target plate associated with a voltage for physical vapor deposition;
a first shutter plate that comprises a first set of openings; and
a second shutter plate that comprises a second set of openings, wherein the first shutter plate and the second shutter plate are located between the target plate and a substrate, wherein the first shutter plate rotates at a first speed, and wherein the second shutter plate rotates at a second speed that is different than the first speed.

19. The system of claim 18, wherein the first shutter plate and the second shutter plate rotate in a corresponding direction.

20. The system of claim 18, wherein the first shutter plate and the second shutter plate rotate in opposite directions.
